(19) United States
(12) Patent Application Publication
(10) Pub. No.: US 2015/0144060 A1
(43) Pub. Date: May 28, 2015

(54) CLUSTER-BATCH TYPE SYSTEM FOR PROCESSING SUBSTRATE

(71) Applicant: Terasemicon Corporation, Hwaseong-si (KR)

(72) Inventor: Sang Kwon PARK, Osan-si (KR)

(21) Appl. No.: 14/546,194

(22) Filed: Nov. 18, 2014

(30) Foreign Application Priority Data
Nov. 25, 2013 (KR) 10-2013-0144079

(51) Int. Cl. C23C 16/458; H01L 21/67; H01L 21/677; C23C 16/455; C23C 16/46

(52) U.S. Cl. CPC C23C 16/458; C23C 16/455; C23C 16/46; C23C 16/463; H01L 21/67706; H01L 21/67715; H01L 21/67161
USPC 118/719; 414/226.05

(57) ABSTRACT

Disclosed is a cluster-batch type substrate processing system. The cluster-batch type substrate processing system comprises a substrate carry-in section 1 into which a substrate 40 is carried; a substrate conveyance robot 7 to rotate about a rotation axis and perform loading/unloading of the substrate 40; and a plurality of batch type substrate processing apparatuses 9 (9a, 9b) disposed radially around the substrate conveyance robot 7.

### FIELD OF THE INVENTION

The present invention relates to a cluster-batch type substrate processing system. More particularly, the present invention relates to a cluster-batch type substrate processing system in which a plurality of batch type substrate processing apparatuses are disposed radially around a substrate conveyance robot, thereby maximizing efficiency and productivity in processing substrates.

### BACKGROUND

In order to manufacture a semiconductor device, a process of depositing a required thin film on a substrate such as a silicon wafer is essentially performed. For the thin film deposition process, sputtering, chemical vapor deposition (CVD), atomic layer deposition (ALD) and the like are mainly used.

The sputtering refers to a technique for colliding argon ions generated in a plasma state against a surface of a target, and causing a target material released from the surface of the target to be deposited on a substrate as a thin film. The sputtering is advantageous in that a high-purity thin film with excellent adhesiveness can be formed, but has limitation in forming a fine pattern with a high aspect ratio.

The chemical vapor deposition refers to a technique for injecting various gases into a reaction chamber and subjecting the gases induced with high energy such as heat, light, or plasma to a chemical reaction with a reactant gas so that a thin film is deposited on a substrate. The chemical vapor deposition employs a quick chemical reaction, and thus has problems in that it is very difficult to control thermodynamic stability of atoms, and physical, chemical and electric properties of the thin film are deteriorated.

The atomic layer deposition refers to a technique for alternately supplying a source gas and a purge gas as reactant gases so that a thin film is deposited on a substrate at the level of an atomic layer. The atomic layer deposition employs a surface reaction to overcome the limitations of step coverage, and thus is advantageous in that it is suitable to form a fine pattern with a high aspect ratio, and the thin film exhibits excellent electrical and physical properties.

An atomic layer deposition apparatus may be classified into single-wafer type in which substrates are loaded into a chamber one by one to perform a deposition process, and batch type in which a plurality of substrates are loaded into a chamber to perform a deposition process in a batch.

FIG. 1 is a side cross-sectional view illustrating a conventional batch type atomic layer deposition system, FIG. 2 is a plan cross-sectional view of FIG. 1, and FIG. 3 is a perspective view illustrating a substrate processing apparatus of the conventional batch type atomic layer deposition system.

Referring to FIGS. 1 and 2, the conventional batch type atomic layer deposition system is configured such that a front-opening unified pod (FOUP) 4 containing a plurality of substrates 40 may be carried into the system through a load port 2 and stored in a FOUP stocker 3. The FOUP 4 seated and stored on a FOUP stocking rack 3a of the FOUP stocker 3 may come in close contact with a front-opening interface mechanical standard (FIMS) door 6 by a FOUP conveyance robot 5 moving along a vertically extending FOUP conveyance robot rail 5a. A substrate conveyance robot 7 may use a conveyance fork 7a to unload the substrates 40 from a FOUP 4′, which has come in close contact with the FIMS door 6 and then opened at one side, and move downward along a substrate conveyance robot rail 7b to stack the substrates 40 on a support bar 55 of a boat 50.

Referring to FIGS. 1 to 3, a substrate processing apparatus 8 of the conventional batch type atomic layer deposition system may comprise a process tube 10 which forms a chamber 11 in which the substrates 40 are loaded and a deposition process is performed. In addition, components like a gas supply section 20 and a gas discharge section 30 required for the deposition process may be installed within the process tube 10. The boat 50 in which the substrates 40 are stacked may be moved upward and downward. When the boat 50 is moved upward, a base 51 may be hermetically coupled with the process tube 10 and a protrusion 53 may be inserted into the process tube 10.

The above conventional batch type atomic layer deposition system is provided with only one substrate processing apparatus 8 to perform the substrate processing process, and thus has a problem in that the productivity of the substrates processed per unit time is low. In addition, the operational efficiency is poor since a substrate carry-in section 1 and the substrate conveyance robot 7 convey the substrates 40 only to the one substrate processing apparatus 8. Further, the operation of the entire batch type atomic layer deposition system should be interrupted when the substrate processing apparatus 8 is stopped due to a trouble occurring therein.

In addition, the above substrate processing apparatus 8 of the conventional batch type atomic layer deposition system may have a chamber 11 space having a height enough to accommodate about one hundred substrates 40. Accordingly, a large amount of process gas should be supplied to fill the chamber 11 so as to perform the deposition process, which may cause problems of increase in the consumption of time required for supplying the process gas and the waste of the process gas, and increase in the consumption of time required for discharging the large amount of process gas existing within the chamber 11 after the deposition process.

In addition, a problem may occur that it is difficult to control a source gas and a purge gas so that the atomic layer deposition may be properly performed on all of the about one hundred stacked substrates 40 within the unnecessarily spacious chamber 11, and consequently, the atomic layer deposition may be properly performed only on the substrates 40 disposed at specific positions.

In order to solve the above-described problems, a method of performing the atomic layer deposition on some (about 25 sheets) of the substrates 40 has been used in which the substrates 40 are disposed only at the specific positions where the atomic layer deposition may be properly performed, and dummy substrates 41 are inserted at the positions where the atomic layer deposition is incompletely performed. However, this method has also failed to solve the problems of increase in the waste of the process gas and the consumption of time required for discharging the process gas.

Referring again to FIG. 3, in the substrate processing apparatus 8 of the conventional batch type atomic layer deposition system, a distance d1′ between the substrates 40 and an inner circumferential surface of the process tube 10 is greater than a distance d2′ between the substrates 40 and the gas supply section 20 (i.e., d1′>d2′). That is, the conventional batch type atomic layer deposition apparatus has a problem of unnecessary increase in the volume of the chamber 11 inside the process tube 10 since the components like the gas supply section 20 and the gas discharge section 30 are installed within the process tube 10 (or the chamber 11).

In addition, the conventional atomic layer deposition apparatus generally uses the process tube 10 in a vertical form, which is ideal for easily withstanding the pressure within the chamber 11. However, an upper space 12 of the vertical chamber 11 may cause problems of the large consumption of time for supplying and discharging the process gas and the waste of the process gas.

### SUMMARY OF THE INVENTION

The present invention has been contrived to solve all the above-mentioned problems of prior art, and one object of the invention is to provide a cluster-batch type substrate processing system in which a plurality of batch type substrate processing apparatuses are disposed radially around a substrate conveyance robot, thereby maximizing efficiency and productivity in processing substrates.

Further, another object of the invention is to provide a cluster-batch type substrate processing system in which an internal space of a batch type substrate processing apparatus for performing a substrate processing process is minimized so that the amount of a substrate processing gas used in the substrate processing process is reduced and the supply and discharge of the substrate processing gas is facilitated, thereby remarkably reducing the time for the substrate processing process.

According to one aspect of the invention to achieve the above-described objects, there is provided a cluster-batch type substrate processing system comprising a substrate carry-in section into which a substrate is carried; a substrate conveyance robot to rotate about a rotation axis and perform loading/unloading of the substrate; and a plurality of batch type substrate processing apparatuses disposed radially around the substrate conveyance robot.

According to the invention, a plurality of batch type substrate processing apparatuses are disposed radially around a substrate conveyance robot, so that efficiency and productivity in processing substrates may be maximized.

Further, according to the invention, a plurality of batch type substrate processing apparatuses are disposed so that even if a trouble occurs in any one of the batch type substrate processing apparatuses, a substrate processing process may be performed through the remaining batch type substrate processing apparatuses.

Furthermore, according to the invention, the size of an internal space of a batch type substrate processing apparatus in which a substrate processing process is performed is minimized to reduce the amount of a substrate processing gas used in the substrate processing process, so that the cost for the substrate processing process may be reduced.

In addition, according to the invention, the size of an internal space of a batch type substrate processing apparatus in which a substrate processing process is performed is minimized to facilitate the supply and discharge of a substrate processing gas used in the substrate processing process, so that the time for the substrate processing process may be remarkably reduced and the productivity of the substrate processing process may be improved.

### BRIEF DESCRIPTION OF THE DRAWINGS

FIG. 1 is a side cross-sectional view illustrating a conventional batch type atomic layer deposition system.

FIG. 2 is a plan cross-sectional view of FIG. 1.

FIG. 3 is a perspective view illustrating a substrate processing apparatus of the conventional batch type atomic layer deposition system.

FIG. 4 is a side cross-sectional view illustrating a cluster-batch type substrate processing system according to one embodiment of the invention.

FIG. 5 is a plan cross-sectional view illustrating the cluster-batch type substrate processing system according to one embodiment of the invention.

FIG. 6 is a plan cross-sectional view illustrating a cluster-batch type substrate processing system according to another embodiment of the invention.

FIG. 7 is a perspective view illustrating a batch type substrate processing apparatus according to one embodiment of the invention.

FIG. 8 is a partial exploded perspective view of FIG. 7.

FIG. 9 is a plan cross-sectional view illustrating the batch type substrate processing apparatus according to one embodiment of the invention.

FIG. 10 is an enlarged perspective view illustrating a gas supply section and a gas discharge section according to one embodiment of the invention.

FIG. 11 is a perspective view illustrating a batch type substrate processing apparatus according to one embodiment of the invention in which a reinforcement rib is coupled onto a top surface thereof.

FIG. 12 is a perspective view illustrating a batch type substrate processing apparatus according to one embodiment of the invention in which heaters are installed on an outer surface thereof.

FIG. 13 is a side cross-sectional view illustrating a cluster-batch type substrate processing system according to one embodiment of the invention in which batch type substrate processing apparatuses are double stacked.

### DETAILED DESCRIPTION OF THE PREFERRED EMBODIMENTS

In the following detailed description of the present invention, references are made to the accompanying drawings that show, by way of illustration, specific embodiments in which the invention may be practiced. These embodiments are described in sufficient detail to enable those skilled in the art to practice the invention. It should be understood that the various embodiments of the invention, although different from each other, are not necessarily mutually exclusive. For example, specific shapes, structures and characteristics described herein may be implemented as modified from one embodiment to another without departing from the spirit and scope of the invention. Moreover, it should be understood that the locations or arrangements of individual elements within each of the disclosed embodiments may be modified without departing from the spirit and scope of the invention. Accordingly, the following detailed description is not to be taken in a limiting sense, and the scope of the invention, if properly described, is limited only by the appended claims together with all equivalents thereof. In the drawings, like reference numerals refer to the same or similar functions throughout the several views, and certain features such as length, area, thickness and shape may be exaggerated for convenience.

It can be understood that the meaning of the term, “substrate” herein encompasses, for example, a semiconductor substrate, a substrate used for a display device such as an LCD or LED display, and a substrate for a solar cell.

Further, the substrate processing process herein means a deposition process, preferably a deposition process using atomic layer deposition, but is not limited thereto and may be understood as encompassing, for example, a deposition process using chemical vapor deposition and a heat treatment process. However, it will be assumed to be a deposition process using atomic layer deposition in the following discussion.

Hereinafter, cluster-batch type substrate processing systems according to embodiments of the present invention will be described in detail with reference to the accompanying drawings.

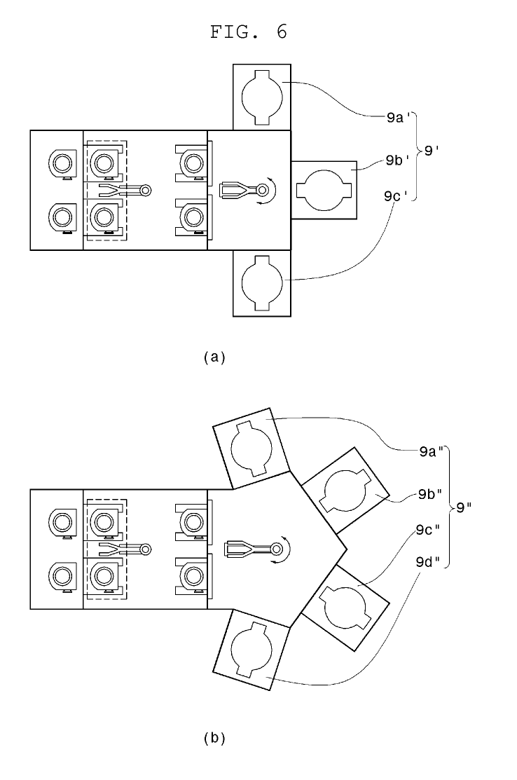

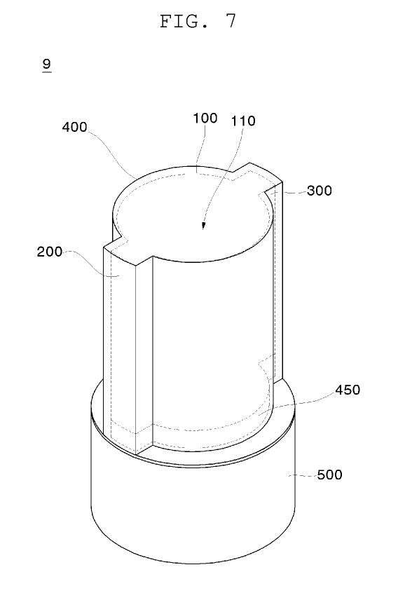

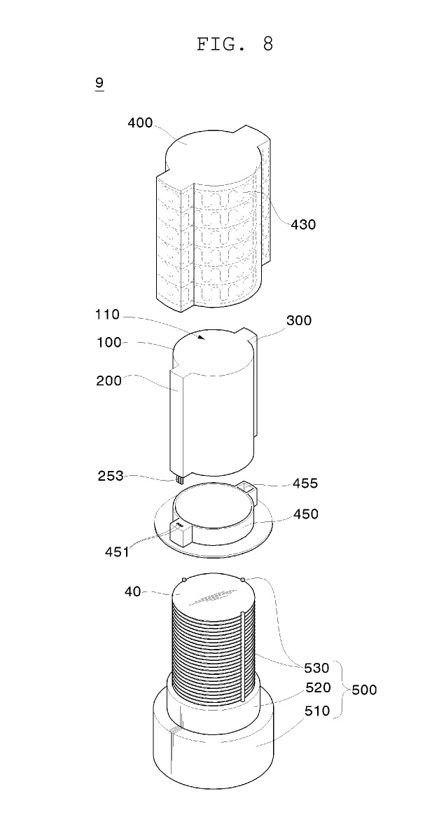

FIG. 4 is a side cross-sectional view illustrating a cluster-batch type substrate processing system according to one embodiment of the invention, FIG. 5 is a plan cross-sectional view illustrating the cluster-batch type substrate processing system according to one embodiment of the invention, and FIG. 6 is a plan cross-sectional view illustrating a cluster-batch type substrate processing system according to another embodiment of the invention.

Referring to FIGS. 4 and 5, the cluster-batch type substrate processing system according to one embodiment of the invention comprises substrate carry-in sections 1 (2, 3, 5, 6), a substrate conveyance robot 7, and batch type substrate processing apparatuses 9 (9a, 9b) radially disposed around the substrate conveyance robot 7. Each of the batch type substrate processing apparatuses 9 may be disposed in mutual contact with one side of the substrate conveyance robot 7 (i.e., a space in which the substrate conveyance robot 7 is disposed). Although FIG. 5 illustrates that two batch type substrate processing apparatuses 9 are disposed around the substrate conveyance robot 7, three batch type substrate processing apparatuses 9′ (9a′, 9b′, 9c′) as shown in (a) of FIG. 6, four batch type substrate processing apparatuses 9″ (9a″, 9b″, 9c″, 9d″) as shown in (b) of FIG. 6, or more batch type substrate processing apparatuses 9 may be disposed radially around the substrate conveyance robot 7. However, for convenience of discussion, it will be assumed herein that two batch type substrate processing apparatuses 9 (9a, 9b) are disposed. Meanwhile, the configurations of the substrate carry-in section 1 and the substrate conveyance robot 7 are well-known in the art, and thus the detailed description thereof except for the main features will be omitted below.

The substrate carry-in section 1 generally refers to the configuration where a substrate 40 is carried in from the outside and brought to the substrate conveyance robot 7. The substrate carry-in section 1 may include a load port 2, a FOUP stocker 3, a FOUP conveyance robot 5, and a FIMS door 6.

A FOUP 4 containing a plurality of substrates 40 may be conveyed through an external FOUP conveyer system (not shown) and seated in the load port 2. In order to increase the throughput of the substrates, there may be provided at least two load ports 2 in which FOUPs 4 are seated.

The FOUP stocker 3 may provide a place where the FOUPs carried in through the load ports 2 are seated on a plurality of FOUP stocking racks 3a and put on standby prior to a substrate processing process. For example, 14 FOUPs 4 may be loaded in the FOUP stocker 3.

The FOUP conveyance robot 5 may convey the FOUPs 4 seated in the load ports 2 to the FOUP stocker 3, or convey the FOUPs 4 seated in the FOUP stocker 3 to the FIMS door 6. The FOUP conveyance robot 5 may be moved upward and downward or rotated along a vertically extending FOUP conveyance robot rail 5a.

The FIMS door 6 may provide a passage through which the substrates 40 within the FOUPs 4 may be conveyed to the batch type substrate processing apparatuses 9 in a clean state. The FOUP 4 conveyed from the FOUP stocker 3 to the FIMS door 6 by the FOUP conveyance robot 5 may be in close contact with and hermetically coupled to the FIMS door 6. In this state, one side of the FOUP 4′ being in close contact with the FIMS door 6 is opened, and the substrates 40 may be carried out through the opened side by the substrate conveyance robot 7. At least two FIMS doors 6 may be provided so as to carry a large number of substrates 40 into the plurality of batch type substrate processing apparatuses 9.

The substrate conveyance robot 7 may perform loading/unloading of the substrates 40 carried in through the substrate carry-in section 1 (i.e., the FIMS door 6) in relation to the batch type substrate processing apparatuses 9. The substrate conveyance robot 7 may be moved upward and downward along a vertical substrate conveyance robot rail 7b which extends vertically, and may be rotated about a rotation axis of the vertical substrate conveyance robot rail 7b. In the state in which the substrate conveyance robot 7 is brought into line with a batch type substrate processing apparatus 9 to be loaded with the substrates 40 while rotating about the rotation axis of the vertical substrate conveyance robot rail 7b, the substrate conveyance robot 7 may extend a conveyance fork 7a to load the substrates 40 into the corresponding batch type substrate processing apparatus 9. Of course, unloading of the substrates 40 out of the batch type substrate processing apparatus 9 is performed in the reverse order of the loading procedure.

The substrate conveyance robot 7 may include five conveyance forks 7a to load five substrates 40 to a boat 500 of the batch type substrate processing apparatus 9 at a time, and thus is advantageous in that the process time may be reduced. For example, when twenty five (25) substrates 40 are loaded in the FOUP 4, the substrate conveyance robot 7 may load the substrates 40 to the boat 500 by moving back and forth five times. Of course, one to five substrates 40 may be selectively loaded to the boat 500 of the batch type substrate processing apparatus 9. For example, when twenty four (24) substrates 40 are loaded in the FOUP 4, the conveyance of the substrates 40 may be performed by conveying five substrates four times and then conveying four substrates. In addition, the number of the conveyance forks 7a can be arbitrarily changed depending on the number of the substrates 40 loaded in the FOUP 4. For example, when twenty four (24) substrates 40 are loaded in the FOUP 4, the number of the conveyance forks 7a may be selected as four or six, which corresponds to a submultiple of 24, so as to enhance the efficiency of conveying the substrates 40.

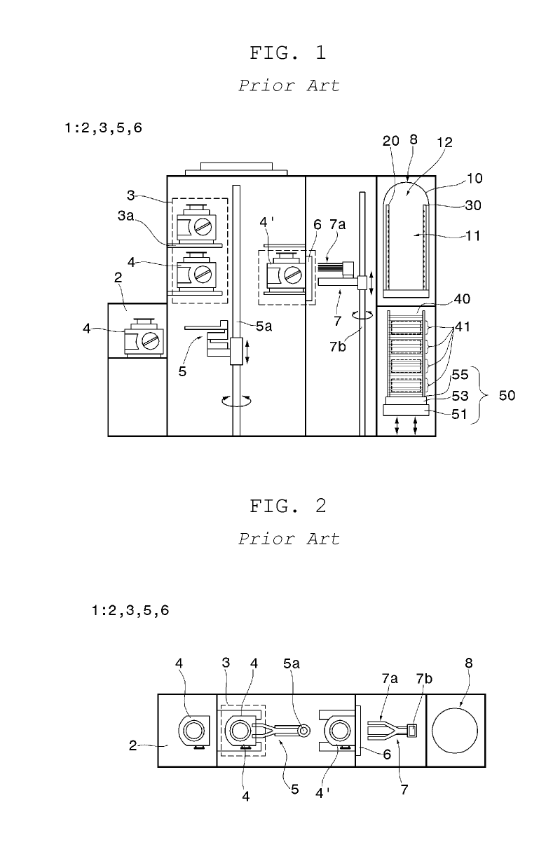

The cluster-batch type substrate processing system according to the invention comprises a plurality of batch type substrate processing apparatuses 9 disposed radially around the substrate conveyance robot 7, which rotates about a rotation axis. Accordingly, the present invention is advantageous in that productivity may be significantly improved depending on the number of the batch type substrate processing apparatuses 9, unlike the prior art (see FIGS. 1 and 2) in which the carry-in section 1 and the substrate conveyance robot 7 perform a substrate processing process in correspondence to only one substrate processing apparatus 8. Further, the substrates 40 carried in through the substrate carry-in section 1 may be directly loaded to/unloaded from the batch type substrate processing apparatuses 9 by the substrate conveyance robot 7 rotating about the rotation axis without moving horizontally, which may remarkably reduce the process time for the conveyance of the substrates 40. This results from disposing the batch type substrate processing apparatuses 9 radially around the substrate conveyance robot 7.

In addition, since the plurality of batch type substrate processing apparatuses 9 are disposed radially around the substrate conveyance robot 7, the present invention is advantageous in that when one of the batch type substrate processing apparatuses 9a, 9b is stopped due to a trouble occurring therein, the other of the batch type substrate processing apparatuses 9a, 9b may be operated so that the operation of the entire system may not be interrupted. As illustrated in FIG. 5, when a trouble occurs in the batch type substrate processing apparatuses 9a, 9b, a user may easily conduct repair, maintenance or the like by entering at a door (not shown) on any one side of each of the batch type substrate processing apparatuses 9a, 9b as indicated by M2 and M3. Of course, when a trouble occurs in the substrate conveyance robot 7, repair, maintenance or the like may also be carried out by entering at a door (not shown) on one side as indicated by M1.

Referring again to FIG. 4, the substrate carry-in section 1 of the cluster-batch type substrate processing system according to the invention may further comprise a cooling section CS to cool the substrates 40 unloaded after the substrate processing process is finished in the batch type substrate processing apparatuses 9. Since the number of substrates 40 to be processed by the plurality of batch type substrate processing apparatuses 9 is considerably increased, the object of the invention can be achieved without affecting the productivity and efficiency only when a large number of substrates 40 may be cooled. Accordingly, at least one FIMS door 6′ may be further provided in the cooling section CS so that the substrates 40 unloaded from the batch type substrate processing apparatuses 9 may be received in a FOUP 4″, which is in close contact with the FIMS door 6′, through the substrate conveyance robot 7 so as to conduct the cooling. Although FIGS. 4 and 5 illustrate that the FOUP 4″ is disposed in the cooling section CS to perform the cooling of the substrates 40, a boat (not shown) may be provided besides the FOUP 4″ to accommodate the substrates 40. In addition, a fan unit (not shown), a ventilation tube (not shown) and the like may be further provided in the cooling section CS so as to enhance cooling efficiency.

Hereinafter, the configuration of the batch type substrate processing apparatuses 9 will be described in detail.

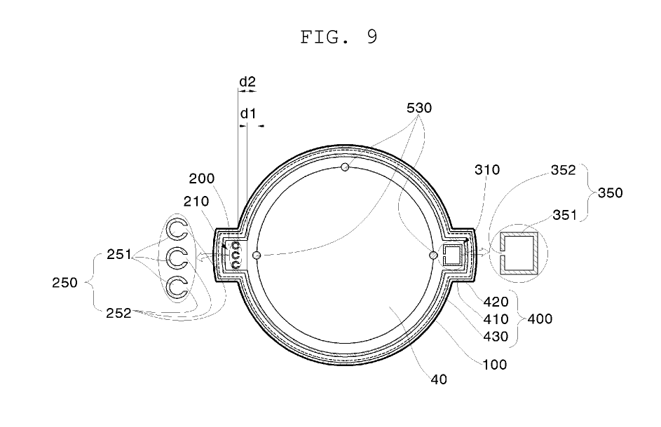

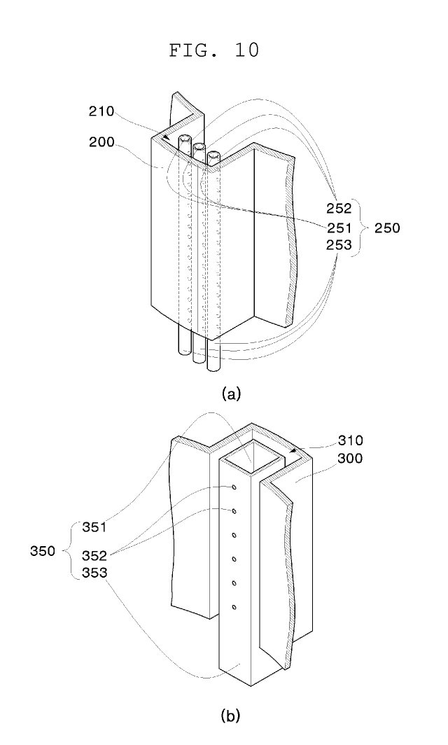

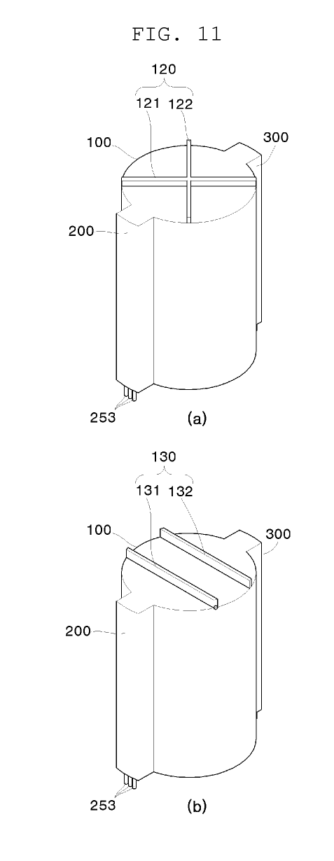

FIG. 7 is a perspective view illustrating a batch type substrate processing apparatus 9 according to one embodiment of the invention, and FIG. 8 is a partial exploded perspective view of FIG. 7. FIG. 9 is a plan cross-sectional view illustrating the batch type substrate processing apparatus according to one embodiment of the invention, and FIG. 10 is an enlarged perspective view illustrating a gas supply section 200 and a gas discharge section 300 according to one embodiment of the invention.

Referring to FIGS. 7 to 9, the batch type substrate processing apparatus 9 according to the present embodiment comprises a substrate processing section 100 and a gas supply section 200.

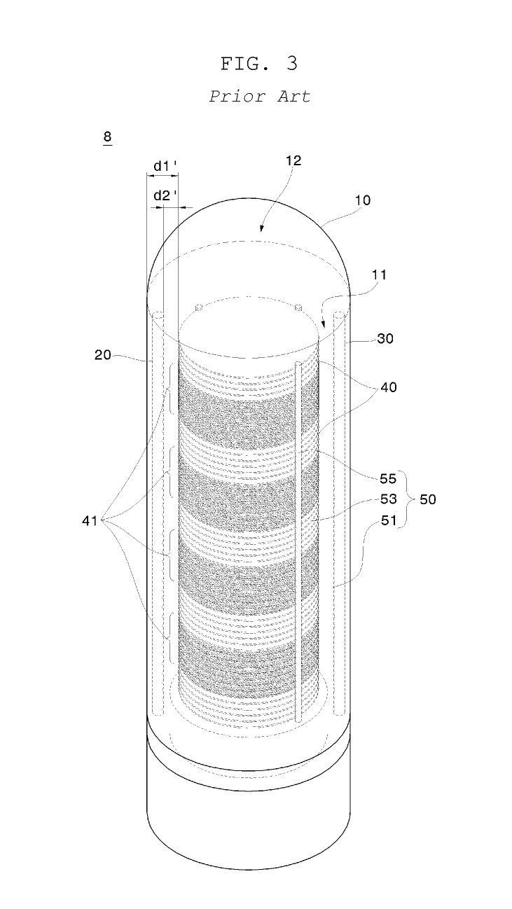

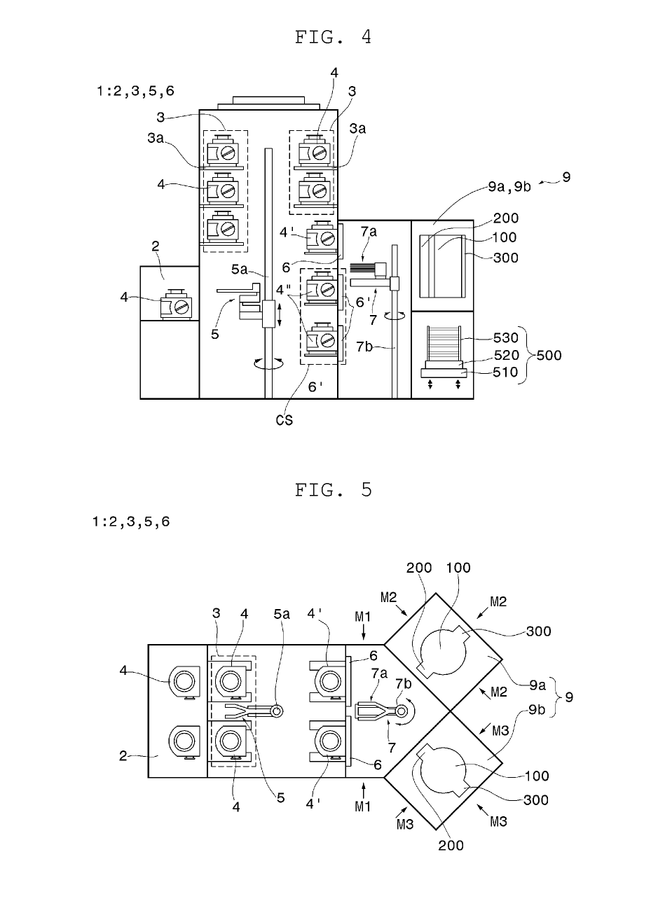

The substrate processing section 100 may function as a process tube. The substrate processing section 100 accommodates a substrate stocker 500 in which a plurality of substrates 40 are stacked, and provides a chamber 110 space in which a substrate processing process such as a deposition film forming process may be conducted. The batch type substrate processing apparatus 9 according to the invention may have a height less than one-half of the height of the conventional batch type substrate processing apparatus 8 to minimize the chamber 110 space, thereby preventing the waste of a process gas and enhancing product yields. Accordingly, it is natural that the chamber 110 space has a size less than one-half of the size of the chamber 11 space illustrated in FIGS. 1 and 3.

The substrate processing section 100 may be made of at least one of quartz, stainless steel (SUS), aluminum, graphite, silicon carbide, and aluminum oxide.

According to one embodiment of the invention, it is most preferable that twenty five substrates 40 are processed in the chamber 110 space of the substrate processing section 100. However, as long as the object of the invention can be achieved, four to sixty four substrates 40 may also be processed. When less than four substrates are accommodated in the substrate processing section 100, the productivity and efficiency may rather be lowered. When more than sixty four substrates are received in the substrate processing section 100, there may occur a problem that is caused by employing a spacious chamber 11 as in the conventional batch type atomic layer deposition system. The user may improve the yields by inserting some dummy substrates 41 at an upper end, a lower end, or a specific location of the stacked substrates 40.

Although the substrate processing apparatus 8 of the conventional batch type atomic layer deposition system has a chamber 11 space in which about one hundred (100) substrates 40 may be accommodated, about twenty to thirty substrates 40 excluding dummy substrates 41 may be processed. Consequently, considering the embodiment of the invention in which twenty five substrates 40 are processed in one substrate processing apparatus 9, fifty substrates 40 may be processed in one substrate processing process in the plurality of batch type substrate processing apparatuses 9. Thus, the present invention is advantageous in that the productivity may be significantly improved as compared to the conventional batch type atomic layer deposition system.

Further, the present invention is advantageous in that the usage of a process gas supplied to the chamber 110 space, which is less than one-half of the conventional one, may be reduced, and a time required for discharging the process gas existing within the chamber 110 after a deposition process may also be reduced.

In addition, the present invention is advantageous in that it is easy to control a source gas and a purge gas for conducting atomic layer deposition within the chamber 110, which is less than one-half of the conventional one, so that the yield and quality of the substrates 40 after completing the substrate processing process can be enhanced.

The gas supply section 200 provides a space 210 in which at least one gas supply flow path 250 is accommodated, and may be formed to protrude from one side of an outer circumferential surface of the substrate processing section 100 so as to supply a substrate processing gas to the internal space 110 of the substrate processing section 100. Here, the gas supply flow path 250 is a passage which may receive the substrate processing gas from the outside and supply it into the substrate processing section 100, and may be in the shape of a pipe or a hollow bore, for example. In particular, the gas supply flow path 250 is preferably configured as a tube so as to precisely control the amount of the supplied substrate processing gas. It will be assumed in the following discussion that the gas supply flow path 250 is consisted of three gas supply pipes 251.

Meanwhile, the gas discharge section 300 provides a space 310 in which at least one gas discharge flow path 350 is accommodated, and may be formed to protrude from the other side of the outer circumferential surface of the substrate processing section 100 (i.e., the opposite side of the gas supply section 200) so as to discharge the substrate processing gas having flowed into the internal space 110 of the substrate processing section 100. Here, the gas discharge flow path 350 is a passage through which the substrate processing gas within the substrate processing section 100 may be discharged to the outside, and may be in the shape of a pipe or a hollow bore, for example. In particular, the gas discharge flow path 350 is preferably configured as a pipe having a diameter larger than that of the gas supply pipe 251 so as to facilitate the discharge of the substrate processing gas. Meanwhile, it is also possible that the gas discharge flow path 350 is configured in the shape of a hollow bore without being provided with a gas discharge pipe 351, and a pump is connected to the gas discharge flow path 350 so as to pump and discharge the substrate processing gas. It will be assumed in the following discussion that the gas discharge flow path 350 is consisted of one gas discharge pipe 351.

The outer circumferential surface of the substrate processing section 100 may be integrally connected with that of the gas supply section 200. Further, the outer circumferential surface of the substrate processing section 100 may be integrally connected with that of the gas discharge section 300. Considering the above, it is preferable that the materials of the gas supply section 200 and the gas discharge section 300 are the same as that of the substrate processing section 100. The connection between the outer circumferential surfaces of the substrate processing section 100, the gas supply section 200 and the gas discharge section 300 may be implemented by manufacturing each of the substrate processing section 100, the gas supply section 200 and the gas discharge section 300 separately and then joining them together using a welding method or the like. In addition, it may also be implemented by manufacturing the substrate processing section 100 having a predetermined thickness and then performing a cutting process on the portions except those protruding from the one and the other sides on the outer circumferential surface of the substrate processing section 100, so that the substrate processing section 100 may be integrally formed with the gas supply section 200 and the gas discharge section 300.

The batch type substrate processing apparatus 9 according to the present embodiment may further comprise a housing 400 and a substrate stocker 500. The housing 400 is opened at the bottom thereof, and formed in the shape of a cylinder with one side protruding to enclose the substrate processing section 100 and the gas supply section 200. The top side of the housing 400 may be supported and installed on the top surface of the batch type substrate processing apparatus 9a, 9b. Referring to FIG. 9, the housing 400 may be consisted of a unit body 410 in the shape of a bulk with one and the other sides thereof protruding to enclose the outer circumferences of the substrate processing section 100 and the gas supply section 200, or in the shape of a circular ring with one and the other sides thereof protruding vertically, so that the housing 400 may serve as an insulator for creating a thermal environment of the substrate processing section 100 and the gas supply section 200. The outermost surface 420 of the housing 400 may be finished using SUS, aluminum, or the like. In addition, a heater 430 formed by successively connecting bent portions (e.g., in a “U” or “∩” shape) may be installed on an inner surface of the housing 400.

The substrate stocker 500 is installed such that it may be moved upward and downward by means of a known elevator system (not shown), and comprises a main base 510, an auxiliary base 520, and a substrate support 530.

The main base 510 may be formed approximately in the shape of a cylinder and seated on a bottom surface or the like of the batch type substrate processing apparatus 9a, 9b, 9c, 9d. The top surface of the main base 510 is hermitically coupled to a manifold 450 which is coupled to the lower end side of the housing 400.

The auxiliary base 520 is formed approximately in the shape of a cylinder and installed on the top surface of the main base 510. The auxiliary base 520 is formed to have a diameter smaller than the inner diameter of the substrate processing section 100 and inserted in the internal space 110 of the substrate processing section 100. The auxiliary base 520 may be installed to be rotatable in cooperation with a motor (not shown) so that the substrates 40 may be rotated during a substrate processing process in order to secure uniformity of a semiconductor manufacturing process. Further, in order to secure reliability of the process, an auxiliary heater (not shown) for applying heat from the bottom side of the substrates 40 during the substrate processing process may be installed within the auxiliary base 520. The substrates 40 loaded and stored in the substrate stocker 500 may be preheated by the auxiliary heater prior to the substrate processing process.

A plurality of substrate supports 530 are installed to be spaced apart from each other along the peripheral side of the auxiliary base 520. Each of a plurality of support recesses are correspondingly formed on an inner surface of each of the substrate supports 530 facing the center of the auxiliary base 520. The peripheral sides of the substrates 40 are inserted in and supported by the support recesses, so that the plurality of substrates 40 carried in and conveyed by the substrate conveyance robot 7 through the substrate carry-in section 1 are loaded and stored in the boat 500 in a vertically stacked form.

The substrate stocker 500 may be removably coupled to the lower end surface of the manifold 450 while moving upward and downward, and the upper end surface of the manifold 450 is coupled to the lower end surfaces of the substrate processing section 100 and the gas supply section 200. A gas supply connecting pipe 253, which extends from the gas supply pipe 251 constituting the gas supply flow path 250 of the gas supply section 200, is inserted in and communicated with a gas supply communication hole 451 of the manifold 450. A gas discharge connecting pipe 353, which extends from the gas discharge pipe 351 constituting the gas discharge flow path 350 of the gas discharge section 300, is inserted in and communicated with a gas discharge communication hole 455 of the manifold 450. In addition, when the substrate stocker 500 is moved upward so that the top surface of the main base 510 of the substrate stocker 500 is coupled to the lower end surface of the manifold 450, the substrates 40 are loaded into the internal space 110 of the substrate processing section 100 and the substrate processing section 100 may be hermetically sealed. For stable sealing, a sealing member (not shown) may be interposed between the manifold 450 and the main base 510 of the substrate stocker 500.

Referring to FIGS. 8 and 9, the substrate processing section 100 is disposed within the housing 400 in concentricity with the housing 400, and the housing 400 may be installed to enclose the substrate processing section 100, the gas supply section 200 and the gas discharge section 300 which are integrally connected with each other.

The gas supply flow path 250 may be accommodated in the internal space 210 of the gas supply section 200. Referring to (a) of FIGS. 9 and 10, the gas supply flow path 250 comprises a plurality of gas supply pipes 251 formed along the longitudinal direction of the gas supply section 200 and a plurality of ejection holes 252 formed on one side of the gas supply pipes 251 to face the substrate processing section 100. Each of the gas supply pipes 251 is formed with a plurality of ejection holes 252. Further, the gas supply connecting pipe 253 communicated from the gas supply pipe 251 is inserted in and communicated with the gas supply communication hole 451 formed in the manifold 450.

The gas discharge flow path 350 may be accommodated in the internal space 310 of the gas discharge section 300. Referring to (b) of FIGS. 9 and 10, the gas discharge flow path 350 comprises a gas discharge pipe 351 formed along the longitudinal direction of the gas discharge section 300 and a plurality of discharge holes 352 formed on one side of the gas discharge pipe 351 to face the substrate processing section 100. The gas discharge pipe 351 is formed with a plurality of discharge holes 352. Further, the gas discharge connecting pipe 353 communicated from the gas discharge pipe 351 is inserted in and communicated with the gas discharge communication hole 455 formed in the manifold 450.

It is preferable that the ejection holes 252 and the discharge holes 352 are respectively positioned in spaces between each two adjacent substrates 40 supported by the substrate supports 530, so that when the substrate stocker 500 is coupled to the manifold 450 and a plurality of substrates 40 are accommodated in the substrate processing section 100, a substrate processing gas may be uniformly supplied to the substrates 40 and may be easily drawn and discharged to the outside.

Since the gas supply section 200 and the gas discharge section 300 are formed to protrude from the outer circumferential surface of the substrate processing section 100, the distance d2 between the substrates 40 and the gas supply flow path 250 may be equal to or greater than the distance d1 between the substrates 40 and the inner circumferential surface of the substrate processing section 100. That is, unlike the prior art illustrated in FIG. 3 in which the gas supply section 20 or the gas discharge section 30 is disposed in the internal space 11 of the process tube 10 in which a substrate processing process is performed, so that the distance d1′ between the substrates and the inner circumferential surface of the process tube 10 is greater than the distance d2′ between the substrates 40 and the gas supply section 20 (i.e., d1′>d2′), the present invention disposes the gas supply section 200 or the gas discharge section 300 outside the substrate processing section 100 to satisfy a condition of d1≦d2, so that the size of the internal space 110 of the substrate processing section 100 may be reduced to the minimum which enables accommodation of the substrate stocker 500 (or the substrates 40). Accordingly, due to the reduction in the size of the internal space 110 of the substrate processing section 100 in which the substrate processing process is performed, the present invention is advantageous in that the usage of the substrate processing gas and the cost for the substrate processing process may be reduced, and the length of time required for supplying and discharging the substrate processing gas may also be reduced, thereby enhancing the productivity of the substrate processing process.

FIG. 11 is a perspective view illustrating a batch type substrate processing apparatus 9 according to one embodiment of the invention in which a reinforcement rib 120, 130 is coupled onto a top surface thereof.

Unlike the process tube 10 of the conventional batch type substrate processing apparatus 8 being in the shape of a bell, the substrate processing section 100 of the batch type substrate processing apparatus 9 according to the invention is in the shape of a cylindrical column and may have a flat top surface. Since the top surface of the substrate processing section 100 is configured to be flat so as to exclude the upper space 12 of the bell-shaped chamber 11 (see FIGS. 1 and 3) in which the substrates 40 cannot be accommodated, the present invention is advantageous in that the size of the internal space 110 of the substrate processing section 100 may be further reduced. However, in order to address a durability problem which may occur due to the difficulty in evenly distributing internal pressure as compared to the conventional bell-shaped chamber 11, the batch type substrate processing apparatus 9 according to the invention is configured such that a plurality of reinforcement ribs 120, 130 are coupled onto the top surface of the substrate processing section 100.

Although the material of the reinforcement ribs 120, 130 may be the same as that of the substrate processing section 100. Without being limited thereto, however, various materials may be employed as long as the top surface of the substrate processing section 100 may be supported.

The reinforcement ribs 120, 130 may be configured such that a plurality of reinforcement ribs 121, 122 are disposed to intersect each other and coupled onto the top surface of the substrate processing section 100 as illustrated in (a) of FIG. 11, and a plurality of reinforcement ribs 131, 132 are disposed to run parallel to each other and coupled onto the top surface of the substrate processing section 100 as illustrated in (b) of FIG. 11. The reinforcement ribs 120, 130 may be coupled to the top surface of the substrate processing section 100 using a welding method or the like.

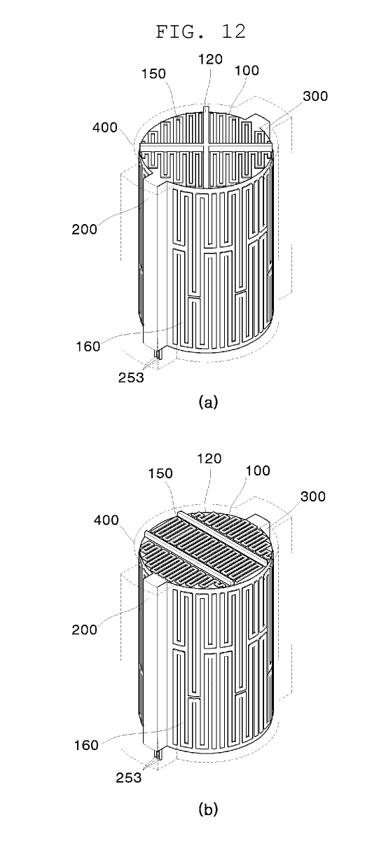

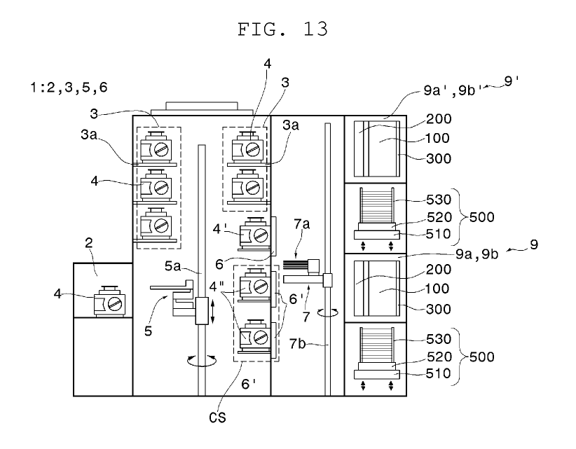

FIG. 12 is a perspective view illustrating a batch type substrate processing apparatus 9 according to one embodiment of the invention in which heaters 150, 160 are installed on an outer surface thereof.

Referring to FIG. 12, the heaters 150, 160 for heating the substrates 40 may be installed on the top surface and outer circumferential surface of the substrate processing section 100, with the heater 430 being installed on the inner surface of the housing 400 as illustrated in FIG. 8 or without the heater 430 being installed on the inner surface of the housing 400. Although not illustrated, heaters may also be installed on the top surfaces and outer circumferential surfaces of the gas supply section 200 and the gas discharge section 300, as necessary.

The heaters 150, 160 may be formed in the shape of a plate to efficiently transfer heat to the internal space 110 of the substrate processing section 100, and may be formed of any one selected from graphite and carbon composite. Alternatively, the heaters 150, 160 may be formed of any one selected from silicon carbide and molybdenum, or formed of Kanthal.

FIG. 13 is a side cross-sectional view illustrating a cluster-batch type substrate processing system according to one embodiment of the invention in which batch type substrate processing apparatuses 9 are double stacked. The configuration of the cluster-batch type substrate processing system illustrated in FIG. 13 is the same as that of the cluster-batch type substrate processing system illustrated in FIGS. 4 and 5, except that batch type substrate processing apparatuses 9a′, 9b′ are double stacked on the top of the batch type substrate processing apparatuses 9a, 9b. Thus, the description thereof will be omitted.

The height of the batch type substrate processing apparatus 9a, 9a′, 9b, 9b′ is not significantly different from that of the conventional substrate processing apparatus 8 even when a double-stacked structure is formed, because the chamber space 11 is reduced less than one-half of that of the conventional substrate processing apparatus 8. Accordingly, the batch type substrate processing apparatuses 9a, 9a′, 9b, 9b′ having the same configuration may be double stacked vertically to further enhance productivity.

As described above, the cluster-batch type substrate processing system according to the invention is configured such that the plurality of batch type substrate processing apparatuses 9 are disposed radially around the substrate conveyance robot 7 which is rotated about the rotation axis, thereby maximizing the productivity of substrate processing and the efficiency of substrate conveyance. Further, the usage of the substrate processing gas may be reduced to save the cost for the process and the time required for supplying and discharging the substrate processing gas may be reduced to enhance the process efficiency.

In addition, the productivity of substrate processing and the process efficiency can be further enhanced by providing the cooling section CS in which a large number of substrates 40 to be processed may be favorably cooled.

Further, the above-mentioned productivity of substrate processing and the process efficiency may be further enhanced by disposing the gas supply section 200 and the gas discharge section 300, which accommodate the gas supply flow path 250 and the gas discharge flow path 350, separately from the substrate processing section 100 in which the substrate processing process is performed, and by forming the top of the substrate processing section 100 to be flat, so that the size of the internal space 110 of the substrate processing section 100 may be minimized.

In addition, by minimizing the size of the internal space 110 of the batch type substrate processing apparatus 9, it becomes easy to control the source gas and purge gas for performing atomic layer deposition, and thus the yield and quality of products can be enhanced.

Moreover, the operational efficiency is good since the substrate conveyance robot 7 conveys the substrates 40 to the plurality of batch type substrate processing apparatuses 9. Further, the operation of the entire system may not be interrupted even when a trouble occurs, and repair and maintenance of each of the batch type substrate processing apparatuses 9 may be easily performed.

Although the present invention has been illustrated and described above with reference to preferred embodiments, the present invention is not limited to the above-described embodiments, and various changes and modifications may be made by those skilled in the art to which the present invention pertains without departing from the spirit and scope of the present invention. It should be noted that such modifications and changes will fall within the scope of the present invention as defined in the appended claims.

What is claimed is:

1. A cluster-batch type substrate processing system comprising:
a substrate carry-in section into which a substrate is carried;
a substrate conveyance robot to rotate about a rotation axis and perform loading/unloading of the substrate; and
a plurality of batch type substrate processing apparatuses disposed radially around the substrate conveyance robot.

2. The cluster-batch type substrate processing system of claim 1, wherein two batch type substrate processing apparatuses are disposed, and the batch type substrate processing apparatuses are disposed in mutual contact with one side of the substrate conveyance robot.

3. The cluster-batch type substrate processing system of claim 1, wherein the substrate carry-in section comprises:
a load port;
a FOUP stocker to store a FOUP carried in through the load port;
a FOUP conveyance robot to convey the FOUP from the load port to the FOUP stocker, or from the FOUP stocker to a FIMS door; and
the FIMS door to provide a passage through which the substrate is carried out from the FOUP to the substrate conveyance robot.

4. The cluster-batch type substrate processing system of claim 3, wherein the substrate carry-in section further comprises:
a cooling section to cool the substrate unloaded from the batch type substrate processing apparatuses.

5. The cluster-batch type substrate processing system of claim 1, wherein the substrate conveyance robot includes five conveyance forks which are capable of conveying 1 to 5 substrates.

6. The cluster-batch type substrate processing system of claim 1, wherein on the top of the batch type substrate processing apparatuses, batch type substrate processing apparatuses are double stacked.

7. The cluster-batch type substrate processing system of claim 1, wherein each of the batch type substrate processing apparatuses is capable of processing 4 to 64 substrates.

8. The cluster-batch type substrate processing system of claim 1, wherein the batch type substrate processing apparatus comprises:
a substrate processing section to accommodate and process a plurality of substrates stacked in a substrate stocker; and
a gas supply section formed on one side of an outer circumferential surface of the substrate processing section to accommodate at least one gas supply flow path in which a substrate processing gas flows and to supply the substrate processing gas to the substrate processing section, and
wherein d1≦d2, where d1 is a distance between the substrates and an inner circumferential surface of the substrate processing section and d2 is a distance between the substrates and the gas supply flow path.

9. The cluster-batch type substrate processing system of claim 8, further comprising:
a gas discharge section formed on the other side of the outer circumferential surface of the substrate processing section to accommodate at least one gas discharge flow path in which the substrate processing gas flows and to discharge the substrate processing gas supplied to the substrate processing section.

10. The cluster-batch type substrate processing system of claim 9, wherein the outer circumferential surface of the substrate processing section is integrally connected with an outer circumferential surface of the gas supply section, and
wherein the outer circumferential surface of the substrate processing section is integrally connected with an outer circumferential surface of the gas discharge section.

11. The cluster-batch type substrate processing system of claim 9, wherein the gas supply flow path comprises a plurality of gas supply pipes formed along a longitudinal direction of the gas supply section, and a plurality of ejection holes formed on one side of the gas supply pipes to face the substrate processing section.

12. The cluster-batch type substrate processing system of claim 11, wherein the gas discharge flow path comprises a gas discharge pipe formed along a longitudinal direction of the gas discharge section, and a plurality of discharge holes formed on one side of the gas discharge pipe to face the substrate processing section.

13. The cluster-batch type substrate processing system of claim 8, wherein the substrate processing section is in the shape of a cylindrical column, and a top surface of the substrate processing section is flat.

14. The cluster-batch type substrate processing system of claim 13, wherein a plurality of reinforcement ribs are coupled onto the top surface of the substrate processing section.

15. The cluster-batch type substrate processing system of claim 14, the plurality of reinforcement ribs are disposed to intersect or run parallel to each other and coupled onto the top surface of the substrate processing section.

16. The cluster-batch type substrate processing system of claim 8, wherein heaters are installed on the outer circumferential surface and top surface of the substrate processing section.

17. The cluster-batch type substrate processing system of claim 16, wherein the heaters are formed in the shape of a plate.

18. The cluster-batch type substrate processing system of claim 8, wherein a bottom surface of the substrate processing section is opened,
a bottom-opened housing is installed to enclose the substrate processing section and the gas supply section, and
the substrate stocker is installed to load the plurality of substrates to the substrate processing section while moving upward and downward.

19. The cluster-batch type substrate processing system of claim 18, wherein the substrate stocker is removably coupled to a lower end surface of a manifold while moving upward and downward, and an upper end surface of the manifold is coupled to lower end surfaces of the substrate processing section and the gas supply section, and
wherein the substrates are loaded to the substrate processing section when the substrate stocker is coupled to the lower end surface of the manifold.

20. The cluster-batch type substrate processing system of claim 12, wherein when the substrate stocker in which the plurality of substrates are stacked is accommodated in the substrate processing section, the ejection holes and the discharge holes are respectively positioned in spaces between each two adjacent substrates supported by the substrate stocker.
